(19) United States
(12) Patent Application Publication
(10) Pub. No.: US 2017/0108971 A1
(43) Pub. Date: Apr. 20, 2017

(54) OLED SUBSTRATE, DISPLAY DEVICE, WEARABLE DEVICE, DRIVING METHOD AND COMPENSATION CIRCUIT

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Shengji YANG, Beijing (CN); Xue DONG, Beijing (CN); Hailin XUE, Beijing (CN); Xiaochuan CHEN, Beijing (CN); Haisheng WANG, Beijing (CN); Weijie ZHAO, Beijing (CN); Yingming LIU, Beijing (CN)

(21) Appl. No.: 15/206,687

(22) Filed: Jul. 11, 2016

(30) Foreign Application Priority Data
Oct. 19, 2015 (CN) 201510679440.9

(51) Int. Cl. G06F 3/041; H01L 27/32; G06F 1/16; G06F 3/044; G09G 3/3225

(52) U.S. Cl. CPC G06F 3/0412; G06F 3/0416; G06F 3/044; G09G 3/3225; G06F 1/163; G06F 1/1643; H01L 27/323; H01L 27/3276; G06F 2203/04103; G09G 2320/0626

(57) ABSTRACT

The present disclosure provides in embodiments an OLED substrate, a display device, a wearable device, a driving method and a compensation circuit. The OLED substrate comprises: a base substrate and at least one electrode located on the base substrate, the at least one electrode acting as a cathode in a display stage and the at least one electrode acting as a touch electrode in a touch stage, wherein, each of the electrode comprises two triangular sub-electrodes isolated from each other.

### CROSS-REFERENCE TO RELATED APPLICATION

This application claims the benefit and priority of Chinese Patent Application No. 201510679440.9 filed Oct. 19, 2015. The entire disclosure of the above application is incorporated herein by reference.

### FIELD

The present disclosure relates to the field of display technology, and particularly, to an OLED substrate, a display device, a wearable apparatus, a driving method and a compensation circuit.

### BACKGROUND

This section provides background information related to the present disclosure which is not necessarily prior art.

With the rapid development of display technology, Touch Screen Panel has gradually extended all over people's life. Currently, the touch panel can be divided, in accordance with the structure, into: Add on Mode Touch Panel, On Cell Touch Panel, as well as In Cell Touch Panel. Among them, the Add on Mode Touch Panel is a liquid crystal display panel with a touch function formed by bonding together a touch panel and a liquid crystal display (LCD) panel which are produced separately, and has shortcomings such as higher production cost, low light transmittance, thicker modules. The In Cell Touch Panel is to embed touch electrodes of the touch panel inside the liquid crystal display panel, which can reduce the thickness of the entire module and can greatly reduce manufacturing costs of the touch panel, favored by major panel manufacturers.

Organic Light Emitting Display (OLED) is one of hotspots in today's flat panel display research field. Compared with liquid crystal display, OLED has advantages like low power consumption, low production cost, self-luminous, wide viewing angle and fast response and so on. Currently, in the field of display like mobile phone, PDA, digital camera, OLED has begun to replace conventional LCD display panel. Pixel drive circuit design is the core technology content of OLED display, and has an important research significance.

Meanwhile, for In Cell Touch technology with relatively large technical difficulties, because this technology has characteristics of being compatible with display panel process, favored more and more by panel manufacturers, many companies also list the In Cell Touch technology development as the main direction of company technology research.

### SUMMARY

This section provides a general summary of the disclosure, and is not a comprehensive disclosure of its full scope or all of its features.

One of technical problems to be solved by the present disclosure is to integrate In Cell Touch technology with OLED display technology so as to embed the touch function inside an OLED display panel, without additional processes and costs.

The present disclosure provides in embodiments an OLED substrate, comprising a base substrate and at least one electrode located on the base substrate, the at least one electrode acting as a cathode in a display stage and the at least one electrode acting as a touch electrode in a touch stage, wherein each of the electrode comprises two triangular sub-electrodes isolated from each other.

In an embodiment, the two triangular sub-electrodes are disposed such that the outer contour of the shape of the combination of the two triangular sub-electrodes is a parallelogram.

In an embodiment, the parallelogram is a rectangle.

In an embodiment, the OLED substrate further includes a sub-electrode wiring, the sub-electrode wiring connecting from opposite two sides of the parallelogram to the two triangular sub-electrodes and extending along the opposite two sides of the parallelogram.

In an embodiment, the sub-electrode wiring further connects from a peripheral region of the base substrate to a backplane of the base substrate.

In an embodiment, the two sub-electrodes are made of a transparent conductive oxide, and the sub-electrode wiring is made of metal.

In an embodiment, the touch electrode includes a touch driving electrode and a touch sensing electrode.

In an embodiment, the two triangular sub-electrodes are the same.

In an embodiment, edges of the two triangular sub-electrodes tilted relative to pixels have a stepped shape.

The present disclosure further provides in embodiments a display device, comprising an OLED substrate according to the above embodiment.

The present disclosure further provides in embodiments a wearable device, comprising a display device according to the above embodiment.

The present disclosure further provides in embodiments a driving method of a display device according to the above embodiment, comprising:

controlling light-emitting of each pixel in a display stage; and

scanning a touch signal and internal control signals of all pixels simultaneously in a touch stage.

In an embodiment, the touch signal and the internal control signals of all the pixels are scanned simultaneously by synchronously driving the touch electrode and touch lines below the touch electrode.

In an embodiment, an anode of the OLED substrate is set by a black insertion mode.

The present disclosure further provides in embodiments a pixel compensation circuit performing a driving method according to the above-described embodiment.

Further aspects and areas of applicability will become apparent from the description provided herein. It should be understood that various aspects of this disclosure may be implemented individually or in combination with one or more other aspects. It should also be understood that the description and specific examples herein are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a schematic view of an OLED touch module;

FIG. 2 is a schematic view of an OLED touch module according to an embodiment of the present disclosure;

FIG. 3 is a schematic view of an OLED substrate according to an embodiment of the present disclosure;

FIG. 4 shows a schematic view of a touch electrode pattern;

FIG. 5 shows schematic views of an OLED structure adopting conventional process and FIC process respectively; and

FIG. 6 shows a schematic view of another touch electrode pattern.

Corresponding reference numerals indicate corresponding parts or features throughout the several views of the drawings.

### DETAILED DESCRIPTION

Example embodiments will now be described more fully with reference to the accompanying drawings.

In the description of the present disclosure, it should be noted that orientation or position relations indicated by the terms “upper”, “lower”, “top”, “bottom” are based on the drawings, only for facilitating and simplifying the description of the present description, rather than indicating or implying that the indicated device or element must have a particular orientation, be constructed and operated in a particular orientation, and hence cannot be construed as limiting the present disclosure.

Furthermore, in the description of the present disclosure, unless otherwise specified, “a plurality of” means two or more.

Here various preferred embodiments of the present disclosure will be described in detail with reference to the drawings.

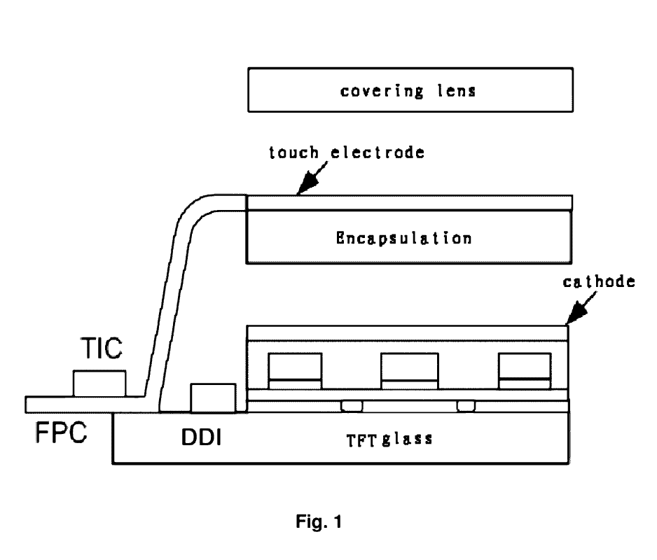

FIG. 1 shows an OLED module using a multi-layer on cell touch solution. In this solution, Add on Mode is used, in which a cathode and a sensor electrode (i.e., a touch electrode) of a display unit are designed as two independent components, and both are isolated from each other through an Encapsulation. The sensor is further connected to a flexible printed circuit board (FPC), and a covering lens is located above the sensor electrode.

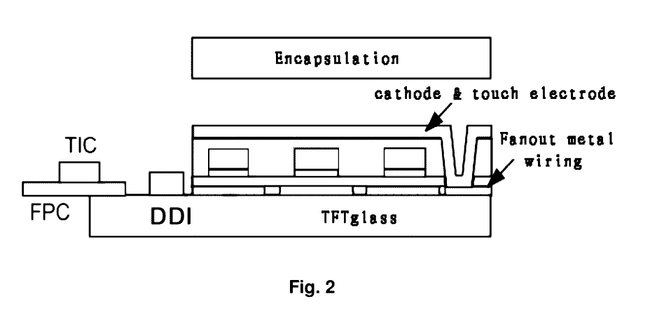

FIG. 2 shows a schematic view of an OLED touch module according to an embodiment of the present disclosure. As shown in FIG. 2, the cathode and the touch electrode originally isolated in FIG. 1 are integrated into a same layer, so that the touch function is embedded inside an OLED display panel, without additional processes and costs. In particular, in a way to divide and multiplex the cathode electrode, the cathode electrode is divided into a number of triangular sub-electrodes, each triangular sub-electrode forming a touch electrode, to achieve the integration of In Cell Touch technology and OLED technology. Further, according to an embodiment of the present disclosure, each triangular sub-electrode wiring further connects from the peripheral region (e.g., Fanout metal wiring) of the base substrate to a backplane of the base substrate. Those skilled in the art will appreciate that the OLED touch module of the embodiment of the present disclosure may be a mutual capacitance touch or a self-capacitive touch type, wherein the self-capacitance touch type is preferred.

Compared to the touch module in FIG. 1, the touch module according to an embodiment of the present disclosure uses In Cell Touch, can effectively solve the problem that, when applied to a flexible OLED, this Add on Mode Touch touch is difficult to achieve because transparent conductive material acting as the cathode such as indium tin oxide (ITO) is inflexible, and thus greatly expands the application range of the touch solution.

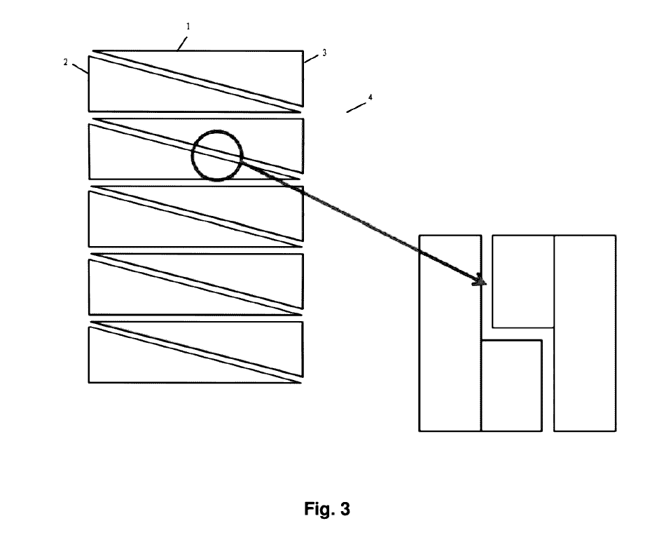

FIG. 3 is a schematic view of an OLED substrate according to an embodiment of the present disclosure, and further shows a way to divide and multiplex the cathode electrode abovementioned. It should be noted that, for the sake of clarity, FIG. 3 only schematically shows a cathode electrode layer of the OLED substrate. As shown in FIG. 3, the OLED substrate according to the embodiment of the present disclosure comprises: a base substrate (not shown) and at least one electrode 1 located on the base substrate, the at least one electrode 1 acting as a cathode electrode in a display stage and the at least one electrode 1 acting as a touch electrode in a touch stage, and each electrode 1 comprising two triangular sub-electrodes 2 and 3 isolated from each other. It should be understood, since pixel is the minimum display unit, edges of the triangular sub-electrodes may have a stepped shape, and an enlarged portion of FIG. 3 shows this situation. According to an embodiment of the present disclosure, the touch electrode includes a touch driving electrode and a touch sensing electrode. Further, according to an embodiment of the present disclosure, the cathode electrode may include any transparent conductive oxide material known in the art such as ITO (indium tin oxide). It should be noted, in FIG. 3, although the two sub-electrodes have a right triangle shape, this is only a preferred embodiment, and the present disclosure does not limit the type of triangular shape of the sub-electrodes.

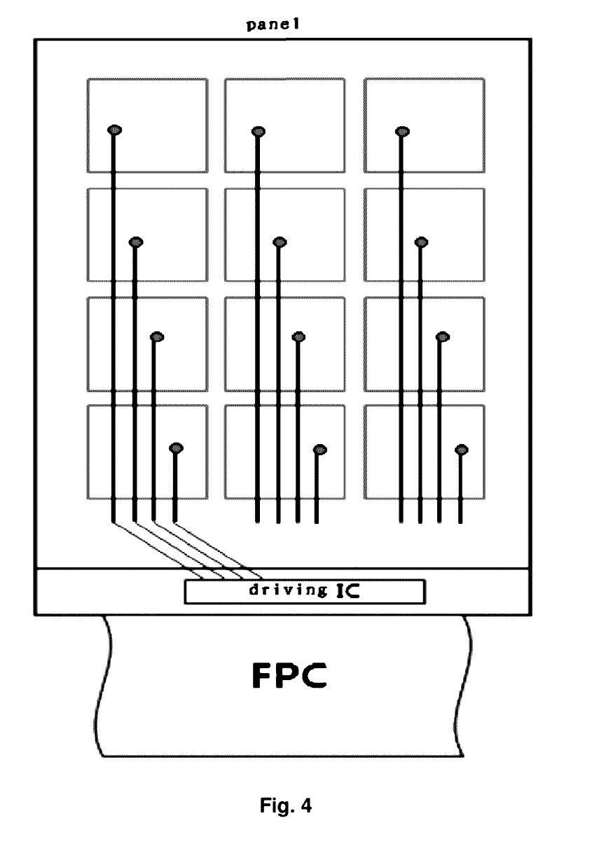

FIG. 4 illustrates a touch electrode pattern, wherein the touch electrode is a square, and a metal wiring connects to the touch electrode through a Via on the touch electrode, and guides to a driving IC below the panel across the surface of the touch electrode. According to an embodiment of the present disclosure, this Via formed on the touch electrode can be removed, substantially increasing the aperture ratio, for example, the aperture ratio can be increased by about 33%, with the same pixels per inch (PPI) and using the same manufacturing process.

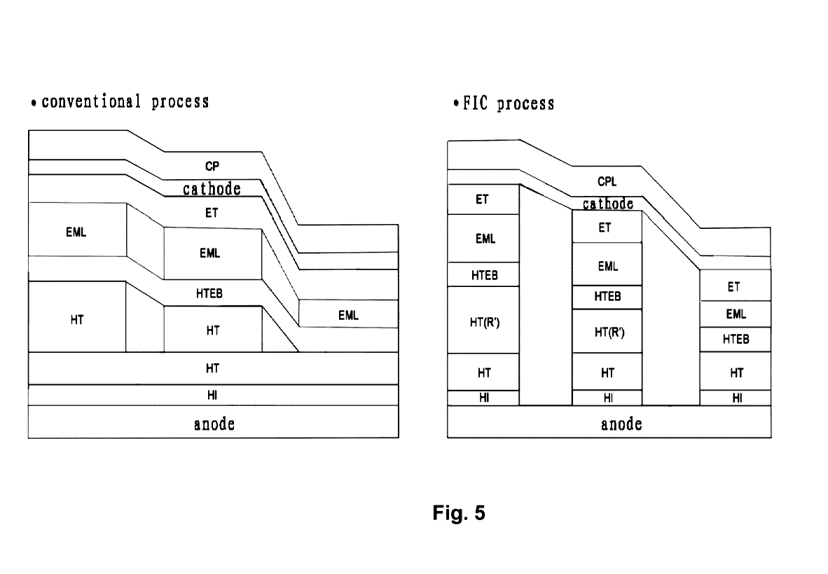

Further, since the Via is located above the electrode, the wiring structure of FIG. 4 needs to use Full in Cell process instead of conventional process. FIG. 5 further shows differences between the conventional process and the FIC process. As shown in FIG. 5, in the conventional process, an open mask is used to evaporate an electron transport layer (ET), an HTEB layer, a hole transport layer (HT) and a hole injection layer (HI); on the contrary, in the FIC process, the manufacture of each layer needs to use FMM, which causes the material consumed by common layers like the electron transporting layer, the HTEB layer, the hole transport layer and the hole injection layer to increase three times, and the excessive use of FMM will lead to low manufacturing yield. However, according to an embodiment of the present disclosure, a conduction Via is no longer disposed on the touch electrode, for example, the conduction Via can be transferred to the peripheral portion of the display panel, so that in addition to being able to increase the aperture ratio, the conventional process also may be used for manufacturing, thereby saving manufacturing costs and increasing manufacturing yields.

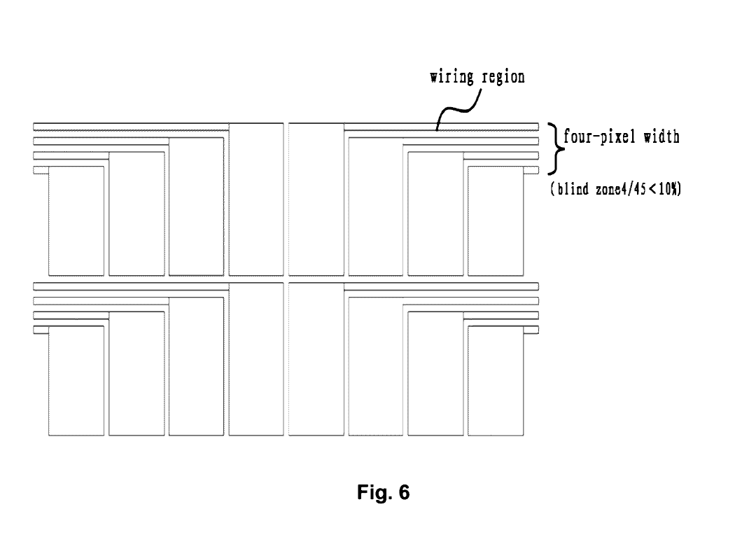

FIG. 6 shows another touch electrode pattern, wherein the cathode electrode and the electrode wiring are located in a display region, whereby the electrode wiring takes up too much available area, leading to the occurrence of a touch blind zone. For example, for every four cathode electrodes shown in FIG. 6, the touch blind zone caused by the wiring region at least occupies a four-pixel width. In contrast, according to an embodiment of the present disclosure, since the cathode electrode is divided into triangular cathode electrodes, the electrode wiring can connect from both sides to the triangular cathode electrode, whereby the electrode wiring no longer occupies limited available area, which greatly reduces the touch blind zone and increases the touch sensitivity.

Further, according to an embodiment of the present disclosure, since the electrode wiring may not be located in the display region, the electrode wiring can be formed using low resistance metal individually. Compared to the solution of FIG. 6 in which the electrode wiring also need to use an ITO material, this can significantly reduce the resistance value of the wiring region, eliminating the IR-Drop problem caused because the wiring region has a high resistance.

In summary, in the embodiments of the present disclosure, the touch function is embedded inside the OLED display panel by dividing the cathode electrode into triangle cathode electrodes in a way to divide and multiplex the cathode electrode, each triangle cathode electrode acting as a touch electrode. The solution in the embodiments of the present disclosure has at least the following advantages.

1. With respect to the characteristics that a wearable device (with smaller Panel size) does not need multi-touch, the triangular cathode electrode in an embodiment of the present disclosure can be satisfactorily applied to wearable devices, implementing the sensing of a single-finger gesture.

2. The upper and lower electrode conduction can be easily implemented, with less pad and IC costs saved, and a narrow-bezel panel can be easily implemented. The touch electrode and the connecting metal wiring connect at the edge portion of the panel, without affecting the pixel aperture ratio. In addition, on the premise of ensuring that the number of pads meets the requirements, a two-way driving may be used.

3. The conduction Via is disposed in the peripheral portion of the panel, whereby there is no need to add FMM and further there is no need to increase FMM costs and material costs.

4. The resistance value of the metal wiring for connecting the cathode electrode is low, and the IR drop issues substantially are not present.

According to an embodiment of the present disclosure, the two triangular sub-electrodes 2 and 3 are set such that the outer contour of the combination of the two triangular sub-electrodes 2 and 3 is a parallelogram. With this setting, it is possible to effectively reduce the number of pads, thereby reducing the number of ICs used, saving manufacturing costs.

According to an embodiment of the present disclosure, the outer contour of the shape of the combination of the two triangular sub-electrodes 2 and 3 of the OLED substrate may be a square, and FIG. 3 shows the preferred embodiment. With this setting, the OLED substrate has a more compact layout, to further improve the pixel aperture ratio.

According to an embodiment of the present disclosure, the OLED substrate further includes a sub-electrode wiring 4, the sub-electrode wiring connecting from opposite two sides of the parallelogram to the two triangular sub-electrodes 2 and 3 and extending along the opposite two sides of the parallelogram. With this setting, the upper and lower electrode conduction can easily be implemented, the conduction Via is provided only in the peripheral portion of the panel, whereby there is no need for increase in FMM during the manufacture, saving manufacturing costs. Under normal circumstances, since the cathode electrode is made of a transparent conductive oxide such as ITO, its resistance is higher, and in order to reduce the resistance of the touch electrode, preferably, the sub-electrode wiring may be made of low-resistance metal, and preferably the sub-electrode wiring and the cathode electrode are provided in the same layer.

According to an embodiment of the present disclosure, as shown in FIG. 2, the sub-electrode wiring further connects from the peripheral region (e.g., Fanout metal wiring) of the base substrate to the backplane of the base substrate.

According to an embodiment of the present disclosure, preferably, the two triangular sub-electrodes 2 and 3 are the same as each other. With this setting, load matching can be further improved, thereby increasing the touch accuracy.

In short, with the solution of the present disclosure, production costs can be saved and productivity can be improved, on the basis of existing preparation process, without additional processes to separately prepare the touch electrode.

The present disclosure further provides in embodiments a display device, comprising the OLED substrate according to the embodiment of the present disclosure.

The present disclosure further provides in embodiments a wearable device, comprising the display device according to the embodiment of the present disclosure.

The present disclosure further provides in embodiments a driving method of a display device, comprising: controlling light-emitting of each pixel in a display stage; and scanning a touch signal and internal control signals of all pixels simultaneously in a touch stage. With this driving method, effects of the load relative to ground may be effectively counteracted.

According to an embodiment of the present disclosure, preferably, the touch signal and the internal control signals of all the pixels are scanned simultaneously by synchronously driving the touch electrode and touch lines below the touch electrode.

According to an embodiment of the present disclosure, preferably, in the implementation of the above-described driving method, an anode of the OLED need to be set by a black insertion mode, thereby reducing the load relative to ground of the touch electrode to maximum extent, to meet the touch requirements.

The present disclosure further provides in embodiments pixel compensation circuit performing a driving method according to the above-described embodiment.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. An OLED substrate, comprising a base substrate and at least one electrode located on the substrate, the at least one electrode acting as a cathode in a display stage and the at least one electrode acting as a touch electrode in a touch stage, wherein, each of the electrode comprises two triangular sub-electrodes isolated from each other.

2. The OLED substrate according to claim 1, wherein, the two triangular sub-electrodes are disposed such that the outer contour of the shape of the combination of the two triangular sub-electrodes is a parallelogram.

3. The OLED substrate according to claim 2, wherein, the parallelogram is a rectangle.

4. The OLED substrate according to claim 2, wherein, further including a sub-electrode wiring, the sub-electrode wiring connecting from opposite two sides of the parallelogram to the two triangular sub-electrodes and extending along the opposite two sides of the parallelogram.

5. The OLED substrate according to claim 4, wherein, the two sub-electrodes are made of a transparent conductive oxide, and the sub-electrode wiring is made of metal.

6. The OLED substrate according to claim 4, wherein, the sub-electrode wiring further connects from a peripheral region of the base substrate to a backplane of the base substrate.

7. The OLED substrate according to claim 6, wherein, the two sub-electrodes are made of a transparent conductive oxide, and the sub-electrode wiring is made of metal.

8. The OLED substrate according to claim 1, wherein, the touch electrode includes a touch driving electrode and a touch sensing electrode.

9. The OLED substrate according to claim 1, wherein, the two triangular sub-electrodes are the same.

10. The OLED substrate according to claim 1, wherein, edges of the two triangular sub-electrodes have a stepped shape.

11. A display device, comprising the OLED substrate according to claim 1.

12. A wearable device, comprising a display device according to claim 11.

13. A driving method of the display device according to claim 11, comprising:
controlling light-emitting of each pixel in a display stage; and
scanning a touch signal and internal control signals of all pixels simultaneously in a touch stage.

14. The driving method according to claim 13, wherein,
simultaneously scanning the touch signal and the internal control signals of all the pixels by synchronously driving the touch electrode and touch lines below the touch electrode.

15. The driving method according to claim 13, wherein, an anode of the OLED substrate is set by a black insertion mode.

16. A pixel compensation circuit, performing the driving method according to claim 13.

17. A pixel compensation circuit, performing the driving method according to claim 14.

18. A pixel compensation circuit, performing the driving method according to claim 15.
